(19) United States
(12) Patent Application Publication
(10) Pub. No.: US 2023/0344195 A1
(43) Pub. Date: Oct. 26, 2023

(54) MULTI-BEAM SEMICONDUCTOR LASER DEVICE

(71) Applicant: Ushio Denki Kabushiki Kaisha, Tokyo (JP)

(72) Inventors: Yutaka Inoue, Tokyo (JP); Shigeta Sakai, Tokyo (JP); Masato Hagimoto, Tokyo (JP)

(73) Assignee: Ushio Denki Kabushiki Kaisha, Tokyo (JP)

(21) Appl. No.: 18/121,002

(22) Filed: Mar. 14, 2023

(30) Foreign Application Priority Data
Apr. 22, 2022 (JP) 2022-070860

(51) Int. Cl. H01S 5/0234; H01S 5/40; H01S 5/026

(52) U.S. Cl. CPC H01S 5/0234; H01S 5/4031; H01S 5/4087; H01S 5/026

(57) ABSTRACT

A multi-beam semiconductor laser device includes an edge-emitting first semiconductor laser chip and an edge-emitting second semiconductor laser chip. The first semiconductor laser chip and the second semiconductor laser chip are located adjacently to each other in a first direction. The first and second semiconductor laser chips each include a semiconductor substrate and a stacked growth layer including a first conductive cladding layer, a light-emitting layer, and a second conductive cladding layer formed on the semiconductor substrate. The first and second semiconductor laser chips include m (m≥1) and n (n≥1) laser resonators extending in a second direction orthogonal to the first direction, respectively. The m laser resonators of the first semiconductor laser chip are disposed at a position closer to a side where the second semiconductor laser chip is located adjacently than a side where the second semiconductor laser chip is not located adjacently.

### CROSS-REFERENCE TO RELATED APPLICATION(S)

This application claims priority from Japanese Patent Application No. 2022-070860 filed on Apr. 22, 2022. The entire teachings of the above application are incorporated herein by reference.

### BACKGROUND ART

The present disclosure relates to a multi-beam semiconductor laser device.

As a high-power edge-emitting laser, JP-A-2010-245207 proposes a multi-beam semiconductor laser in which a plurality of ridge stripe laser resonators is monolithically integrated.

### SUMMARY OF THE INVENTION

After examining the multi-beam semiconductor lasers described in JP-A-2010-245207, the present inventors have come to recognize the following issues.

As disclosed in JP-A-2010-245207, the overall yield of a chip is examined when a plurality of laser resonators is formed in a single chip. Setting the yield per laser resonator to be Y (Y≤1) allows the yield of a chip in which n laser resonators are formed to be Yⁿ, resulting in decreasing the yield exponentially with the increase in the number of beams n.

An aspect of the present disclosure is made under such a circumstance, and one of the exemplary purposes of the present disclosure is to provide a multi-beam semiconductor laser device with improved yield.

One aspect of the present disclosure relates to a multi-beam semiconductor laser device. The multi-beam semiconductor laser device includes an edge-emitting first semiconductor laser chip and an edge-emitting second semiconductor laser chip. The first semiconductor laser chip and the second semiconductor laser chip are located adjacently to each other in a first direction. The first semiconductor laser chip and the second semiconductor laser chip each include a semiconductor substrate and a stacked growth layer including a first conductive cladding layer, a light-emitting layer, and a second conductive cladding layer formed on the semiconductor substrate. The first semiconductor laser chip includes m laser resonators (m≥1) extending in a second direction orthogonal to the first direction, and the second semiconductor laser chip includes n laser resonators (n≥1) extending in the second direction. The m laser resonators of the first semiconductor laser chip are disposed at a position closer to a side where the second semiconductor laser chip is located adjacently than a side where the second semiconductor laser chip is not located adjacently.

Note that any combination of the above components, and any mutual substitution of the components and expressions of the present disclosure among methods, devices, systems, etc., are also valid as an aspect of the present invention or disclosure. Furthermore, the above-mentioned description does not include all the indispensable features of the present invention or disclosure; hence sub-combinations of these features in the present specification can also be the present invention or disclosure.

An aspect of the present disclosure is capable of improving the yield of multi-beam semiconductor laser devices.

### BRIEF DESCRIPTION OF DRAWINGS

FIG. 1 is a cross-sectional view of a multi-beam semiconductor laser device according to an embodiment.

FIG. 2 is a cross-sectional view illustrating a configuration example of a semiconductor laser chip.

FIG. 3 is a cross-sectional view of a multi-beam semiconductor laser device according to a comparative technology.

FIG. 4 is a diagram illustrating the bonding of a first semiconductor laser chip with a submount in the multi-beam semiconductor laser device in FIG. 1.

FIG. 5 is a cross-sectional view of a multi-beam semiconductor laser device according to Example 1.

FIG. 6 is a cross-sectional view of a multi-beam semiconductor laser device according to Example 2.

FIG. 7 is a cross-sectional view of a multi-beam semiconductor laser device according to Example 3.

FIG. 8 is a cross-sectional view of a multi-beam semiconductor laser device according to Example 4.

FIG. 9 is a cross-sectional view of a multi-beam semiconductor laser device according to Example 5.

FIG. 10 is a diagram illustrating the bonding of a first semiconductor laser chip with a submount in the multi-beam semiconductor laser device in FIG. 9.

FIG. 11 is a diagram illustrating another bonding of the first semiconductor laser chip with the submount in the multi-beam semiconductor laser device in FIG. 9.

FIG. 12 is a cross-sectional view of a multi-beam semiconductor laser device according to Example 6.

FIG. 13 is a cross-sectional view of a multi-beam semiconductor laser device according to Example 7.

FIG. 14 is a diagram illustrating an example of the bonding of a first semiconductor laser chip with a submount in the multi-beam semiconductor laser device of FIG. 13.

FIG. 15 is a diagram illustrating another bonding of a first semiconductor laser chip with a submount in the multi-beam semiconductor laser device of FIG. 13.

FIG. 16 is a cross-sectional view of a multi-beam semiconductor laser device according to Example 8.

FIG. 17 is a diagram illustrating another bonding of a first semiconductor laser chip with a submount in the multi-beam semiconductor laser device of FIG. 16.

FIG. 18 is a cross-sectional view of a multi-beam semiconductor laser device according to Example 9.

### DETAILED DESCRIPTION OF THE EMBODIMENTS

### Overview of the Embodiments

Hereinafter, an overview of some exemplary embodiments of the present disclosure will be described. This overview is intended as a preface to the detailed description that follows, or for a basic understanding of the embodiments. The overview describes some concepts of one or more embodiments in a simplified manner and is not intended to limit the scope of the invention or disclosure. In addition, the overview is not a comprehensive overview of all conceivable embodiments, nor does it limit the indispensable components of embodiments. For convenience, “one embodiment” may be used to refer to one embodiment (Example or Variation Example) or a plurality of embodiments (Examples or Variation Examples) disclosed in the present specification.

A multi-beam semiconductor laser device according to one embodiment includes an edge-emitting first semiconductor laser chip and an edge-emitting second semiconductor laser chip. The first semiconductor laser chip and the second semiconductor laser chip are located adjacently to each other in the first direction. The first semiconductor laser chip and the second semiconductor laser chip each include a semiconductor substrate and a stacked growth layer including a first conductive cladding layer, a light-emitting layer, and a second conductive cladding layer formed on the semiconductor substrate. The first semiconductor laser chip includes m laser resonators (m≥1) extending in a second direction orthogonal to the first direction are formed, and the second semiconductor laser chip includes n laser resonators (n≥1) extending in the second direction. The m laser resonators of the first semiconductor laser chip are disposed at a position closer to a side where the second semiconductor laser chip is located adjacently than a side where the second semiconductor laser chip is not located adjacently.

This configuration enables the plurality of laser resonators to be integrated into a plurality of chips, thus improving the yield compared to the case in which all of the laser resonators are integrated into a single chip. In addition, arranging the m laser resonators formed in the first semiconductor laser chip at a position closer to the second semiconductor laser chip enables an appropriate beam interval in a multi-beam laser.

In one embodiment, the n laser resonators of the second semiconductor laser chip may be disposed at a position closer to a side where the first semiconductor laser chip is located adjacently than a side where the first semiconductor laser chip is not located adjacently. This enables a proper beam interval in a multi-beam laser.

In one embodiment, the first semiconductor laser chip and the second semiconductor laser chip may be mounted to a submount with a junction-down method.

In one embodiment, the m laser resonators (m≥2) may be configured to be electrically and independently driven.

In one embodiment, the semiconductor substrate of the first semiconductor laser chip may be a tilted substrate having a tilted side face located on the side of the second semiconductor laser chip.

In one embodiment, the multi-beam semiconductor laser device may further include a single submount that supports the first semiconductor laser chip and the second semiconductor laser chip.

In one embodiment, when m+n≥3 is set, the (m+n) laser resonators formed in the first semiconductor laser chip and the second semiconductor laser chip may be arranged with substantially equal intervals.

In one embodiment, of the (m+n) laser resonators formed in the first semiconductor laser chip and the second semiconductor laser chip, at least one laser resonator thereof may have an oscillation wavelength different from that of at least another resonator thereof. When used as a light source for an image display device such as a head-mounted display (HMD), for example, the multi-beams having the same wavelength causes image quality degradation such as interference fringes due to the interference nature of the laser light. The above configuration, which makes the wavelengths different, improves image quality. Although introducing a wavelength difference in multiple laser resonators formed in the same chip requires additional ingenuity in process and structure, separating the multiple resonators into the first semiconductor laser chip and the second semiconductor laser chip makes it easy to introduce a large wavelength difference.

In one embodiment, the first semiconductor laser chip and the second semiconductor laser chip may be arranged with a gap that separates them.

### Embodiment

Hereinafter, the present disclosure will be described with reference to the drawings based on suitable embodiments. Identical or equivalent components, members, and processes shown in the respective drawings are marked with the same symbols, and duplicated descriptions are omitted as appropriate. The embodiments are intended to be exemplary rather than to limit the disclosure, and all features and combinations thereof described in the embodiments are not necessarily essential to the disclosure.

The dimensions (thickness, length, width, etc.) of each member described in the drawings may be scaled as appropriate for ease of understanding. Furthermore, the dimensions of a plurality of members do not necessarily represent their relationship in size; although one member A is drawn thicker than another member B on the drawing, the member A may be thinner than the member B, for example.

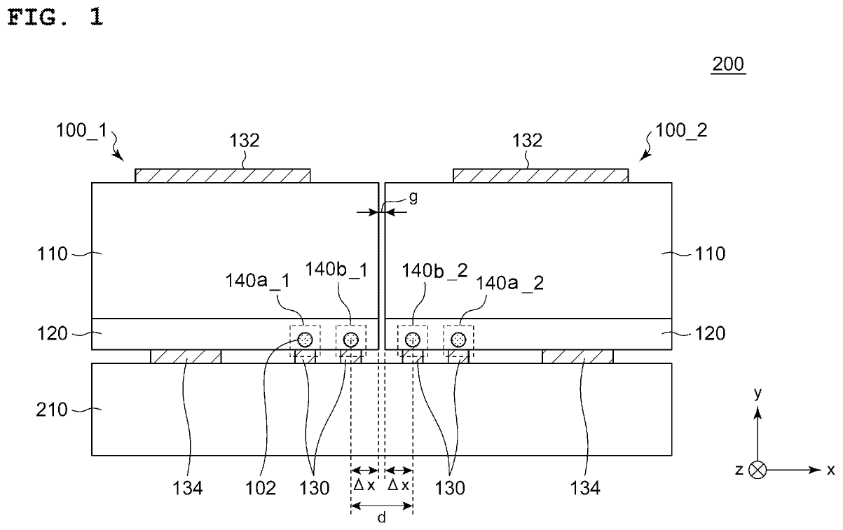

FIG. 1 is a cross-sectional view of a multi-beam semiconductor laser device 200 according to an embodiment. The multi-beam semiconductor laser device 200 includes a first semiconductor laser chip 100_1, a second semiconductor laser chip 1002, and a submount 210.

The first semiconductor laser chip 100_1 and the second semiconductor laser chip 100_2 are of edge-emitting type, and are illustrated in FIG. 1 viewed from the emitting end face thereof. The first semiconductor laser chip 100_1 and the second semiconductor laser chip 1002 are located adjacently in a first direction (x-direction in FIG. 1). The first semiconductor laser chip 100_1 and the second semiconductor laser chip 1002 are arranged to be in non-contact with each other by a gap g that separates them.

The first semiconductor laser chip 100_1 and the second semiconductor laser chip 1002 each have a layered structure of a semiconductor substrate 110 and a stacked growth layer 120. The first semiconductor laser chip 100_1 is formed with m laser resonators 140a_1 and 140b_1 (m≥1) extending in a second direction (z-direction, paper depth direction) orthogonal to the first direction (x-direction) in the in-plane of the chip. The present embodiment sets m=2. In the following description, subscripts a and b are omitted when there is no need to specifically distinguish between laser resonators 140a and 140b in the same chip.

Similarly, the second semiconductor laser chip 100_2 is formed with n laser resonators 140a_2 and 140b_2 (n≥1) extending in the second direction (z-direction). The present embodiment sets n=2.

The emitting edge face of each laser resonator 140 serves as an emitter (light-emitting section) 102. In other words, the entire multi-beam semiconductor laser device 200 includes (m+n) laser resonators 140, and thus the number of the emitters 102 (number of channels) in the multi-beam semiconductor laser device 200 is (m+n).

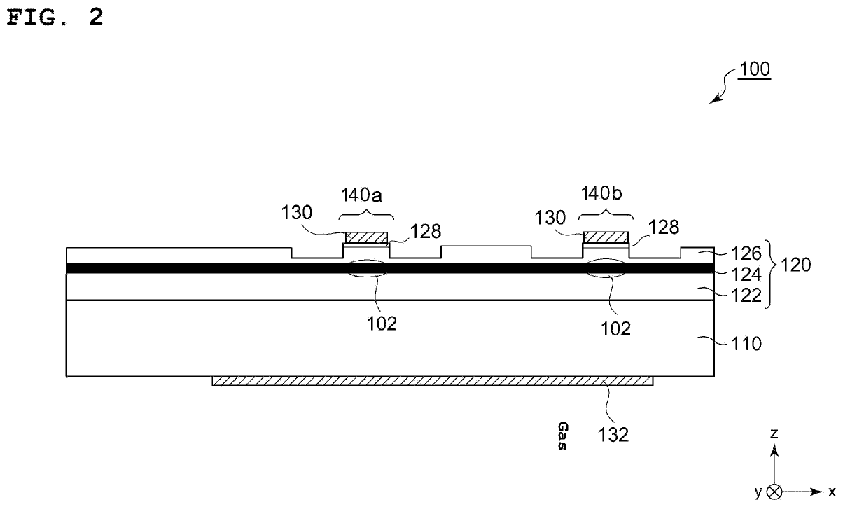

FIG. 2 is a cross-sectional view of an example configuration of the semiconductor laser chip 100. The semiconductor laser chip 100 includes the semiconductor substrate 110 and the stacked growth layer 120. The semiconductor substrate 110 can be made of GaAs in the case of a red laser, and GaN in the case of a blue or green laser.

The stacked growth layer 120 includes an n-type cladding layer 122, a light-emitting layer 124, and a p-type cladding layer 126. On the p-type cladding layer 126, a p-type contact layer 128 can be formed if necessary.

A P-electrode 130 is formed on the upper side of the p-type contact layer 128. An N-electrode 132 is formed on the back surface of the semiconductor substrate 110. Other layers such as an insulating layer are formed on the stacked growth layer 120; however, they are omitted here.

The stacked growth layer 120 is formed with a waveguide structure in which light is confined, and the cleaved surfaces at both ends of this waveguide structure serve as mirrors, forming a laser resonator 140. In this example, two laser resonators 140a and 140b are formed, and the emitters 102 emit beams in the y-direction. A reflective layer with adjusted reflectance may be formed on the cleaved surface.

The waveguide structure can be, for example, a ridge structure. The ridge structure is formed by partially removing the p-type cladding layer 126. The ridge structure is also referred to simply as a ridge or a ridge stripe structure. A bank may be formed between the laser resonators 140a and 140b adjacent to each other. The waveguide structure may be a ridge waveguide of embedded type.

Alternatively, the waveguide structure may be a channeled substrate planar (CSP) structure in which grooves are formed along the waveguide in the semiconductor substrate 110, and the thickness of the n-type cladding layer 122 is relatively thick at the portion of the grooves.

Although the ridge structure and the CSP structure are waveguide structures using refractive index distribution, the present disclosure is not limited thereto; the present disclosure may adopt a gain waveguide structure using gain distribution. These structures can be understood as current constriction structures as well as optical confinement structures.

The configuration example of the semiconductor laser chip 100 has been described above.

With referring back to FIG. 1, the first semiconductor laser chip 100_1 and the second semiconductor laser chip 100_2 are mounted on the submount 210. The submount 210 can use a substrate with excellent heat dissipation properties, and examples of the substrate suitably include a ceramic substrate such as aluminum nitride (AlN).

In the present embodiment, the first semiconductor laser chip 100_1 and the second semiconductor laser chip 1002 are mounted to the submount 210 with a junction-down method. The stacked growth layer 120 of the semiconductor laser chip 100 is mounted in a manner facing the submount 210; specifically, the P-electrode 130 is electrically connected to wiring patterns on the submount 210 by solder. Electrodes 134 are provided primarily to reinforce the mechanical connection of the stacked growth layer 120 that is connected to the submount 210 by solder.

The junction-down mounting has the advantage of high cooling efficiency because the laser resonator 140, which is a heat-generating part, is located closer to the submount 210.

The m laser resonators 140a_1 and 140b_1 of the first semiconductor laser chip 100_1 are arranged at a position closer to a side where the second semiconductor laser chip 100_2 is located adjacently than a side where the second semiconductor laser chip 100_2 is not located adjacently. The n laser resonators 140a_2 and 140b_2 of the second semiconductor laser chip 100_2 are arranged at a position closer to a side where the first semiconductor laser chip 100_1 is located adjacently than a side where the first semiconductor laser chip 100_1 is not located adjacently.

The (m+n) laser resonators 140 are preferably arranged at equal intervals. Typically, intervals d between the laser resonators 140 can be in the order of from 30 μm to 100 μm. In addition, the gap g in the x-direction between the first semiconductor laser chip 100_1 and the second semiconductor laser chip 1002, which are adjacent to each other, can typically be in the order of from 5 μm to 10 μm. Then, a distance Δx from the side of the first semiconductor laser chip 100_1 to the center of the laser resonator 140b_1 and a distance Δx from the side of the second semiconductor laser chip 100_2 to the center of the laser resonator 140b_2 is expressed by Δx=(d−g)/2, where Δx is in the order of from 10 μm to 47.5 μm.

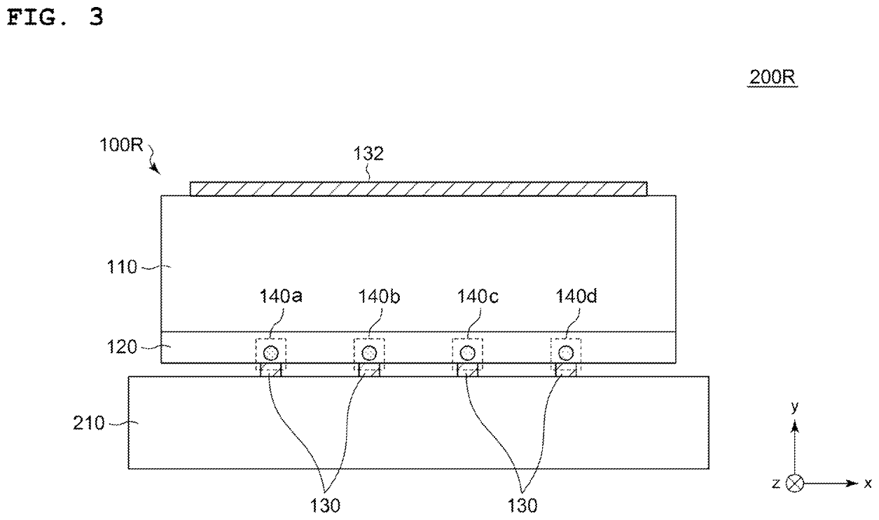

The configuration of the multi-beam semiconductor laser device 200 has been described above. The advantages of the multi-beam semiconductor laser device 200 will become clear by contrasting it with its comparative technology. FIG. 3 is a cross-sectional view of a multi-beam semiconductor laser device 200R according to the comparative technology.

The multi-beam semiconductor laser device 200R includes one semiconductor laser chip 100R, in which (m+n), in other words, four laser resonators 140a to 140d are formed.

The yield of the multi-beam semiconductor laser device 200R according to the comparative technology will be discussed below. When the yield per laser resonator 140 is set to Y, then the probability that the semiconductor laser chip 100R is a good product is Y^{(m+n)}. Hence, when P pieces of the semiconductor laser chips 100R are manufactured, the number of good products is P×Y^{(m+n)}.

Next, the yield of the multi-beam semiconductor laser device 200 according to the embodiment will be examined. The probability that the first semiconductor laser chip 100_1 is a good product is Y^{m}. When P pieces of the first semiconductor laser chips 100_1 are manufactured, the number of good products is P×Y^{m}. Similarly, the probability that the second semiconductor laser chip 1002 is a good product is Yⁿ. When P pieces of the second semiconductor laser chips 100_2 are manufactured, the number of good products is P×Yⁿ. In the case of m−n for ease of understanding, the number of good products of each of the first semiconductor laser chip 100_1 and the second semiconductor laser chip 100_2 is P×Y^{m}, and thus the number of good products of the multi-beam semiconductor laser device 200 is also P×Y^{m}.

The number of good products of the multi-beam semiconductor laser device 200R obtained in the comparative technology is P×Y^{2m}. In contrast, the number of good products of the multi-beam semiconductor laser device 200 obtained in the embodiment is P×Y^{m}. Y<1 gives Y^{2m}<Y^{m}, then P×Y^{2m}<P×Y^{m}. Therefore, the semiconductor laser chip 100 according to the embodiment is capable of improving the yield compared to that with the comparative technology.

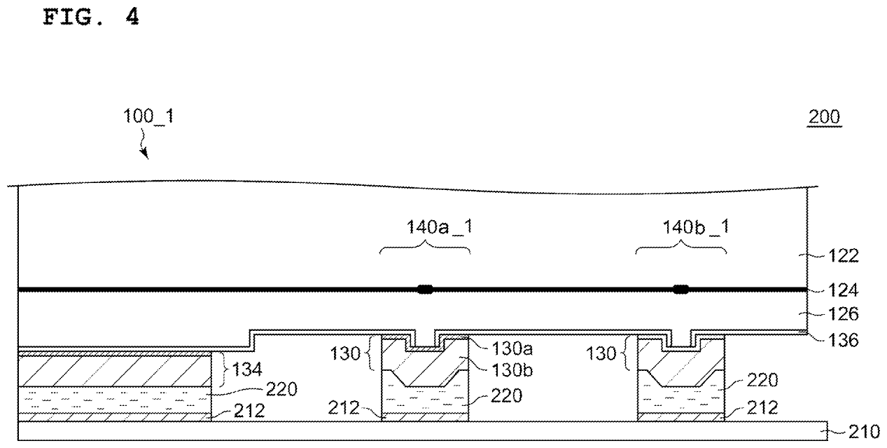

FIG. 4 is a diagram illustrating the bonding of the first semiconductor laser chip 100_1 with the submount 210 in the multi-beam semiconductor laser device 200 of FIG. 1. Since the second semiconductor laser chip 100_2 is similar to the first semiconductor laser chip 100_1, the illustration and description of the second semiconductor laser chip 100_2 are omitted. As described above, the first semiconductor laser chip 100_1 is mounted to the submount 210 with a junction-down method.

The front surface of the p-type cladding layer 126 is covered with an insulating layer 136. The insulating layer 136 has openings at the convex portions of the ridge of the laser resonators 140a_1 and 140b_1. The P-electrodes 130 are formed over the openings to be in contact with the p-type cladding layer 126. For example, the P-electrode 130 may include a base layer 130a formed by vapor deposition and a thick layer 130b formed by plating. The P-type contact layer (not shown) is formed between the p-type cladding layer 126 and the P-electrode 130.

Metal lands (also called submount electrodes) 212 are formed on the front surface of the submount 210. Pattern wirings (not shown) are drawn out from the lands 212 to enable power to be supplied from the outside. Each of the P-electrodes 130 and the electrode 134 of the semiconductor laser chip 100 are electrically and mechanically connected to the corresponding lands 212 by solder 220.

The wider electrode 134, which is provided separately from the P-electrodes 130, is electrically isolated from the P-electrodes 130 of the laser resonators 140a_1 and 140b_1. Hence, the electrode 134 mainly serves to increase the junction strength of the solder 220. This configuration reduces the mounting stress generated in each of the multiple laser resonators 140.

The present disclosure encompasses various devices and methods that can be understood from FIG. 1 or derived from the above description, and is not limited to any particular configuration. Hereinafter, more specific configuration examples and embodiments will be described to facilitate understanding of the essence and operation of the present disclosure and invention and to clarify them rather than to narrow the scope of the present disclosure.

The followings are several examples of the multi-beam semiconductor laser device 200.

### Example 1

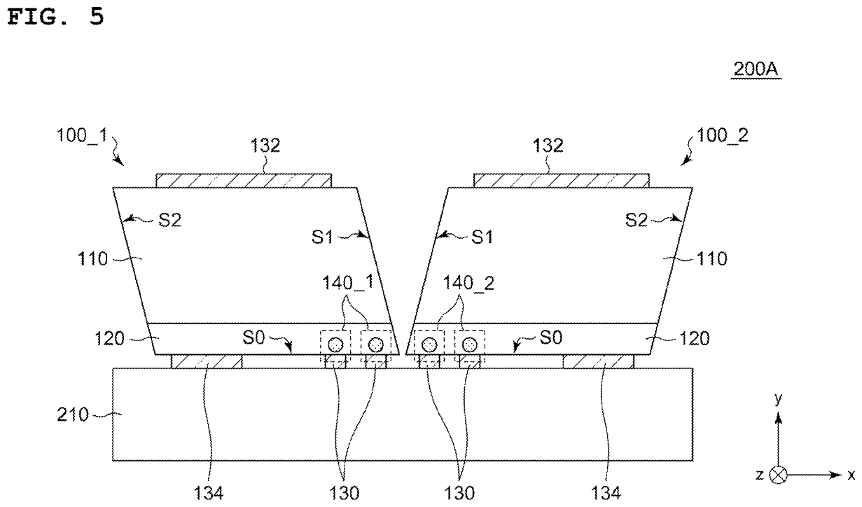

FIG. 5 is a cross-sectional view of a multi-beam semiconductor laser device 200A according to Example 1. In the multi-beam semiconductor laser device 200A, the semiconductor substrate 110 is a tilted substrate whose sides are tilted, and has a first side S1 that is tilted at an acute angle to a surface S0 facing the submount 210 and a second side S2 that is tilted at an obtuse angle.

The first semiconductor laser chip 100_1 and the second semiconductor laser chip 100_2 are arranged in such a manner that the first sides S1 tilted at an acute angle are adjacent to each other. In each semiconductor laser chip 100, the laser resonators 140 are disposed at a location closer to the first side S1, which is tilted at an acute angle, than the second side S2, in other words, the laser resonators 140 are unevenly disposed in the x-direction.

### Example 2

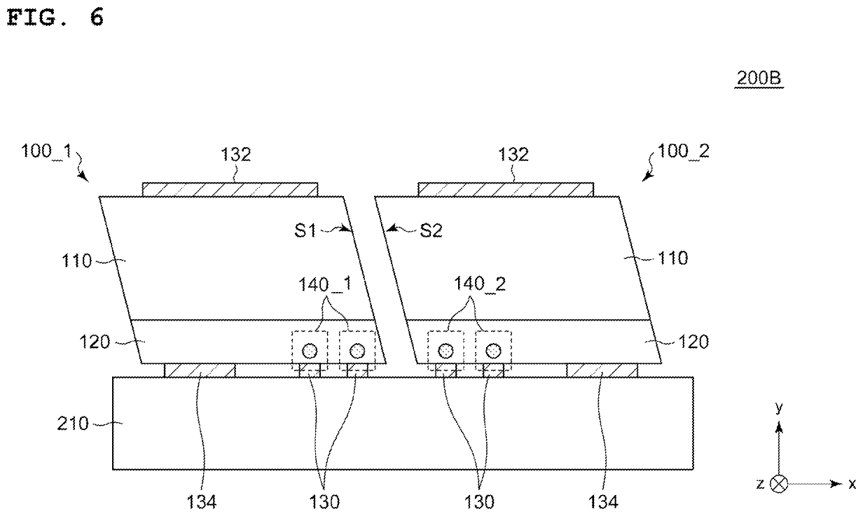

FIG. 6 is a cross-sectional view of a multi-beam semiconductor laser device 200B according to Example 2. In the multi-beam semiconductor laser device 200B, the semiconductor substrate 110 is also a tilted substrate. The first semiconductor laser chip 100_1 and the second semiconductor laser chip 100_2 are arranged in such a manner that the first side S1 tilted at an acute angle and the second side S2 tilted at an obtuse angle are adjacent to each other. In the first semiconductor laser chip 100_1, the laser resonator 140_1 is disposed at a location closer to the first side S1, which is tilted at an acute angle, than a side where the second semiconductor laser chip 1002 is not located adjacently, and in the second semiconductor laser chip 1002, the laser resonator 140_2 is disposed at a location closer to the second side S2, which is tilted at an obtuse angle, than a side where the first semiconductor laser chip 100_1 is not located adjacently.

### Example 3

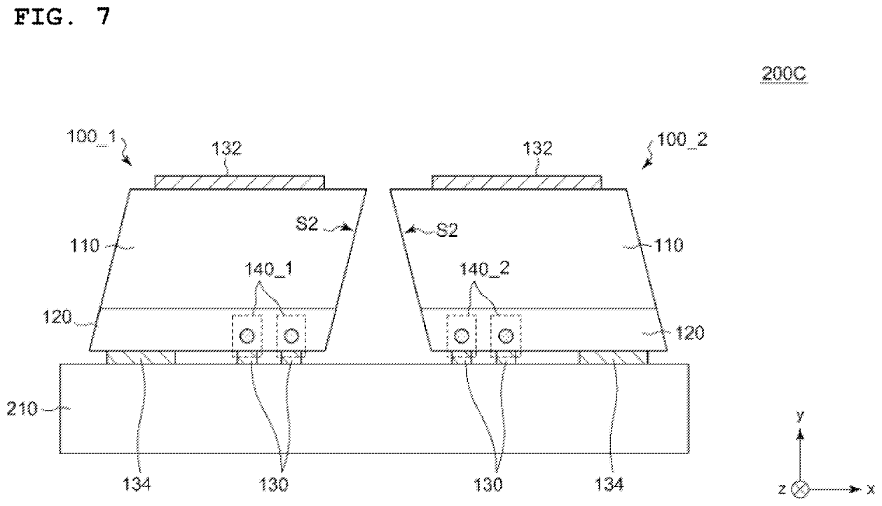

FIG. 7 is a cross-sectional view of a multi-beam semiconductor laser device 200C according to Example 3. In the multi-beam semiconductor laser device 200C, the semiconductor substrate 110 is also a tilted substrate. The first semiconductor laser chip 100_1 and the second semiconductor laser chip 1002 are arranged in such a manner that the second sides S2 tilted at an obtuse angle are adjacent to each other. In the first semiconductor laser chip 100_1, the laser resonator 140_1 is disposed at a location closer to the second side S2, which is tilted at an obtuse angle, than a side where the second semiconductor laser chip 1002 is not located adjacently, and in the second semiconductor laser chip 1002, the laser resonator 140_2 is disposed at a location closer to the second side S2, which is tilted at an obtuse angle, than a side where the first semiconductor laser chip 100_1 is not located adjacently.

### Example 4

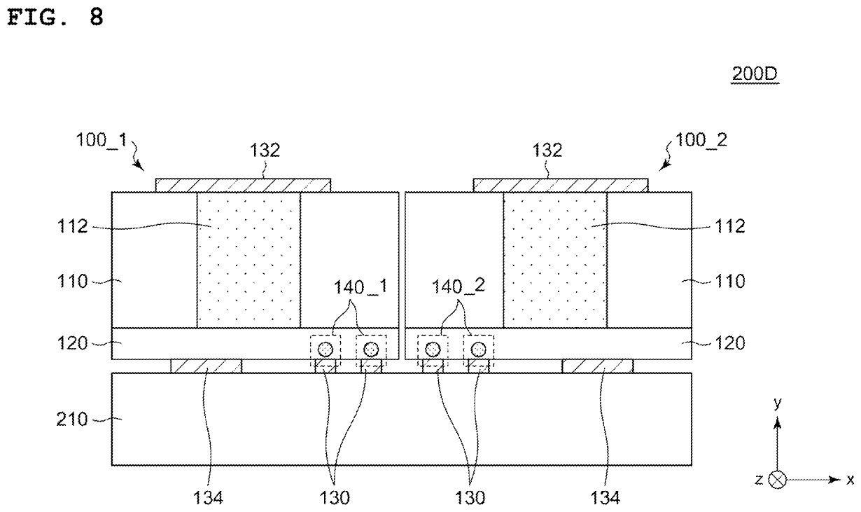

FIG. 8 is a cross-sectional view of a multi-beam semiconductor laser device 200D according to Example 4. In the multi-beam semiconductor laser device 200D, the semiconductor substrate 110 includes a crystal defect aggregation area 112. A method of manufacturing a semiconductor substrate having a crystal defect aggregation area (core) is disclosed in U.S. Pat. No. 3,801,125. In this technology, a heterogeneous substrate such as GaAs is intentionally patterned (e.g., SiO₂), and GaN substrate is grown (thick layer growth) thereon. The patterning section is inverted 180° on the C-axis, which slows the growth rate and creates a depression. There is a phenomenon in which dislocations propagate to the bottom of the depression and aggregate. The technique uses this phenomenon to collect dislocations in the core and create an area with low dislocation density in other areas.

For semiconductor lasers, the crystal defect aggregation area (core) that is made to form a line shape is referred to as a core line. Devices cannot be formed on the core line. Examples of the dimensions of the core line are a width of approximately 40 μm and a period of approximately 400 μm. In the case of using a semiconductor substrate 110 with the crystal defect aggregation area 112, it is difficult to form many of the laser resonators 140 side by side in the single semiconductor substrate 110. In contrast, using the technology according to the embodiment allows the plurality of laser resonators 140 to be formed separately in the two semiconductor laser chips 100_1 and 1002, thereby capable of providing a multi-beam semiconductor laser device 200D with a multi-channel emitter even when using a semiconductor substrate 110 having the crystal defect aggregation area 112.

### Example 5

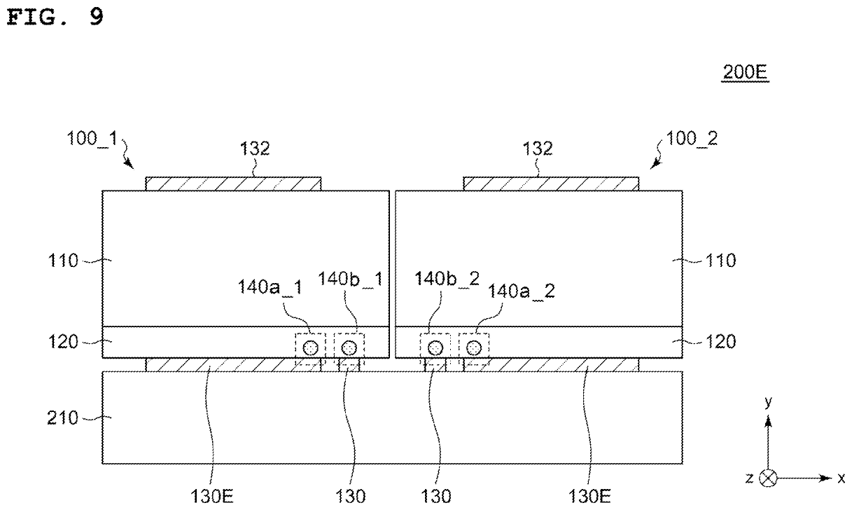

FIG. 9 is a cross-sectional view of a multi-beam semiconductor laser device 200E according to Example 5. In the multi-beam semiconductor laser device 200E, set m=2 and n=2. In each of the first semiconductor laser chips 100_1 and the second semiconductor laser chips 1002, P-electrodes 130E for the outer laser resonators 140a_1 and 140a_2 extend toward the outer edge of the chip to act on increasing the mechanical junction strength by solder. The P-electrodes 130E can be understood as electrodes such that the P-electrode 130 and the electrode 134 of the outer laser resonator 140a_1 and 140a_2 in the respective semiconductor laser chips 100_1 and 100_2 of FIG. 1 are continuously formed.

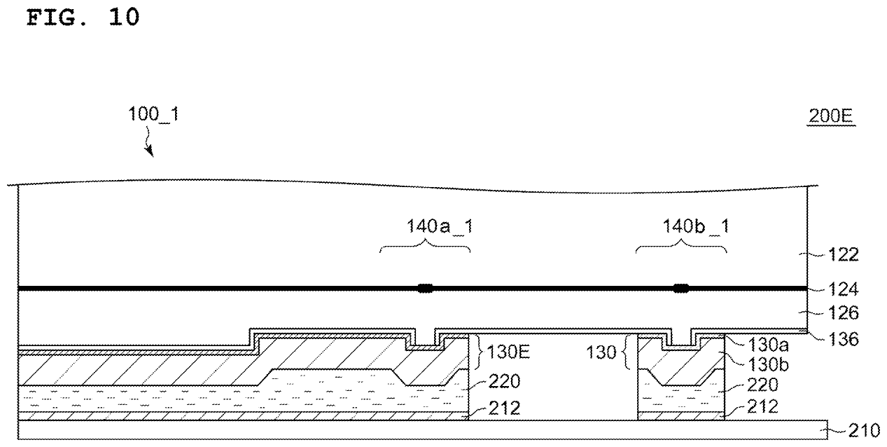

FIG. 10 is a diagram illustrating the bonding of the first semiconductor laser chip 100_1 with the submount 210 in the multi-beam semiconductor laser device 200E of FIG. 9.

Metal land 212 are formed on the front surface of the submount 210. Pattern wiring is drawn out from the lands 212 and can be powered from the outside. The P-electrode 130 and the P-electrode 130E in the semiconductor laser chip 100 each are electrically and mechanically connected to the corresponding lands 212 by solder 220.

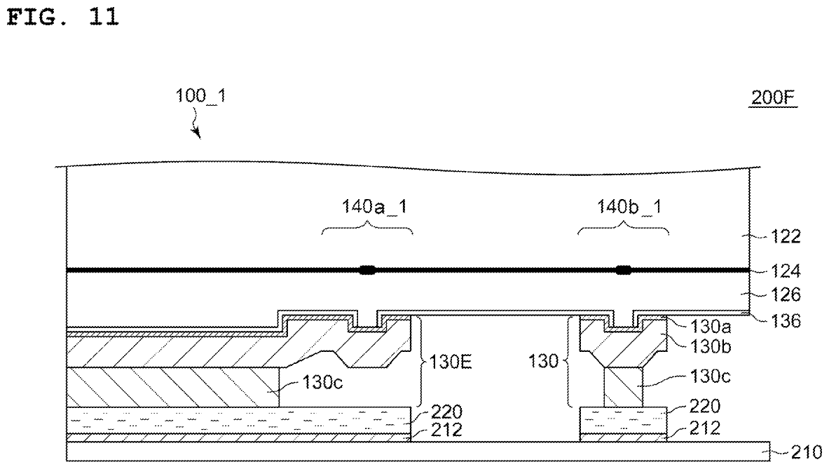

FIG. 11 is a diagram illustrating another bonding of the first semiconductor laser chip 100_1 and the submount 210 in the multi-beam semiconductor laser device 200E of FIG. 9.

In FIG. 11, the P-electrodes 130 and 130E each have a two-stage electrode structure including a post (second thick layer) 130c. Each of the P-electrode 130 and 130E is connected at the post 130c by solder 220. When the P-electrode 130E is focused on, the post 130c is formed to be away from the laser resonator 140a_1. This further reduces the stress that the laser resonator 140a_1 is subjected to. In addition, when the P-electrode 130 is focused on, the plastic deformation of the post 130c further reduces the stress received by posts 130a and 130b and the laser resonator 140b_1.

### Example 6

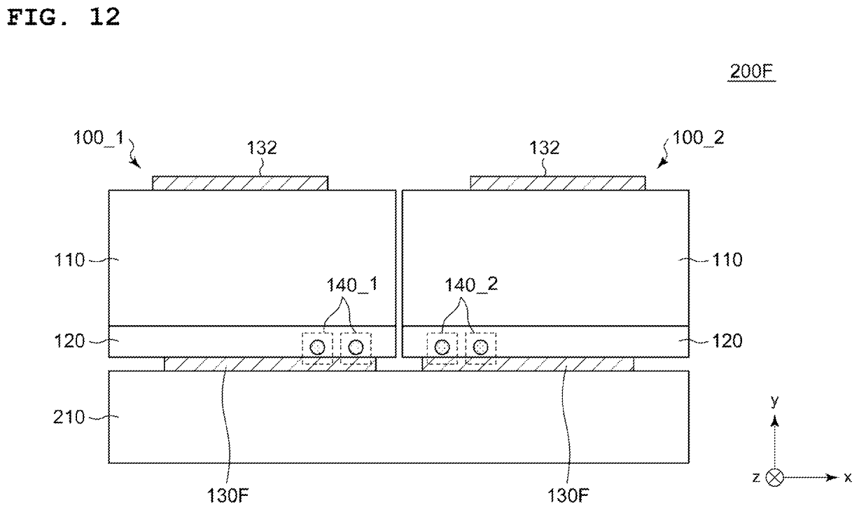

FIG. 12 is a cross-sectional view of a multi-beam semiconductor laser device 200F according to Example 6. In the multi-beam semiconductor laser device 200F, set m=2 and n=2. In each of the first semiconductor laser chip 100_1 and the second semiconductor laser chip 1002, a P-electrode 130F of the two laser resonators 140 is formed electrically continuous. The P-electrode 130F corresponds to an electrode such that the P-electrodes 130 and the electrode 134 of the two laser resonators 140 in each semiconductor laser chip 100 in FIG. 1 are continuously formed.

The configuration of Example 6 is effective when the multiple laser resonators 140 formed in a single chip do not need to be controlled independently.

### Example 7

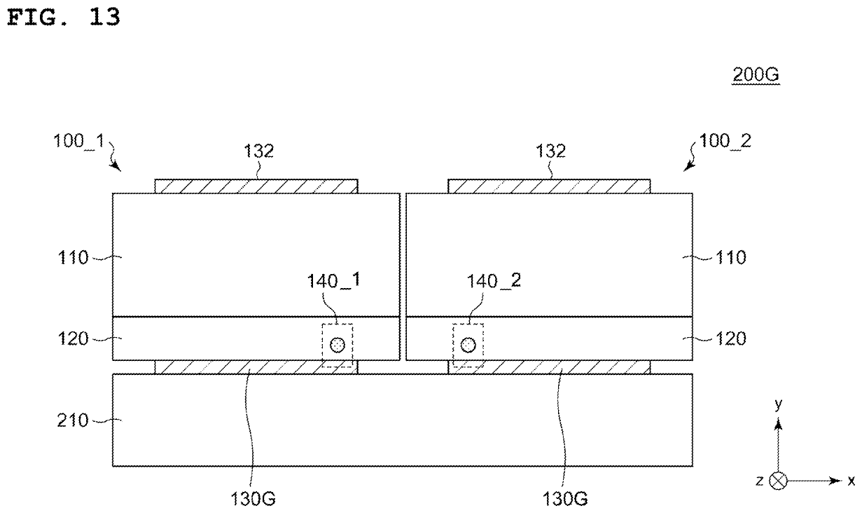

FIG. 13 is a cross-sectional view of a multi-beam semiconductor laser device 200G according to Example 7. In the multi-beam semiconductor laser device 200G, set m=1 and n=1, and the laser resonator 140_1 and 140_2 are formed in the first semiconductor laser chip 100_1 and the second semiconductor laser chip 1002, respectively. P-electrodes 130G have wide widths in the x-direction, thereby enhancing the mechanical junction strength by soldering.

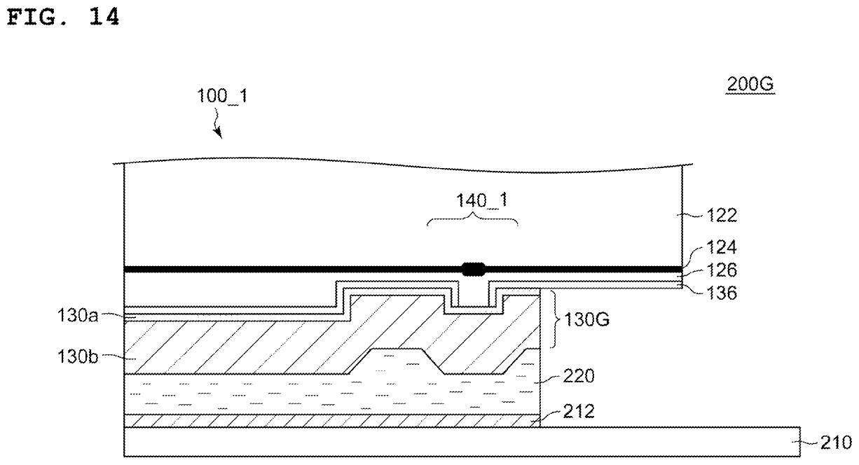

FIG. 14 is a diagram illustrating an example of the bonding of the first semiconductor laser chip 100_1 with the submount 210 in the multi-beam semiconductor laser device 200G of FIG. 13. In FIG. 14, the P-electrode 130G is connected to the land 212 by the solder 220.

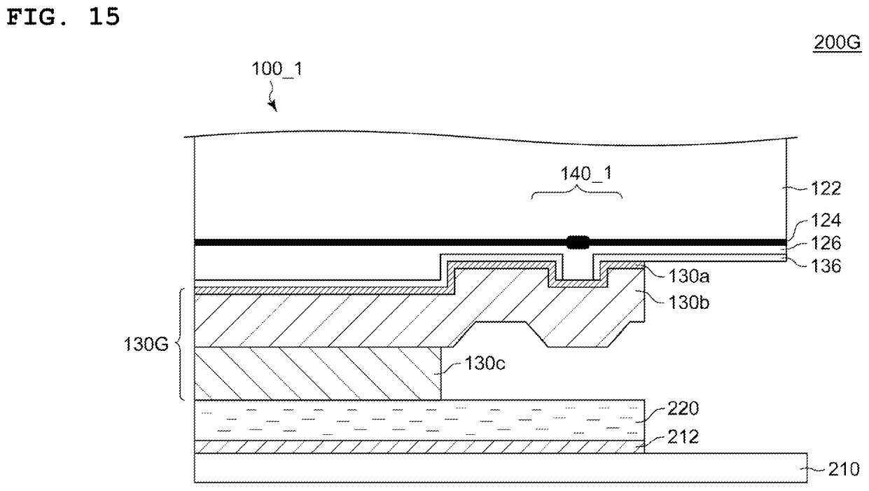

FIG. 15 is a diagram illustrating another bonding of the first semiconductor laser chip 100_1 with the submount 210 in the multi-beam semiconductor laser device 200G of FIG. 13. In FIG. 15, the P-electrode 130G is a two-stage electrode and the post 130c is formed in an area in which the laser resonator 140 does not overlap. This reduces the mounting stresses generated in the laser resonator 140_1 compared to the configuration of FIG. 14.

### Example 8

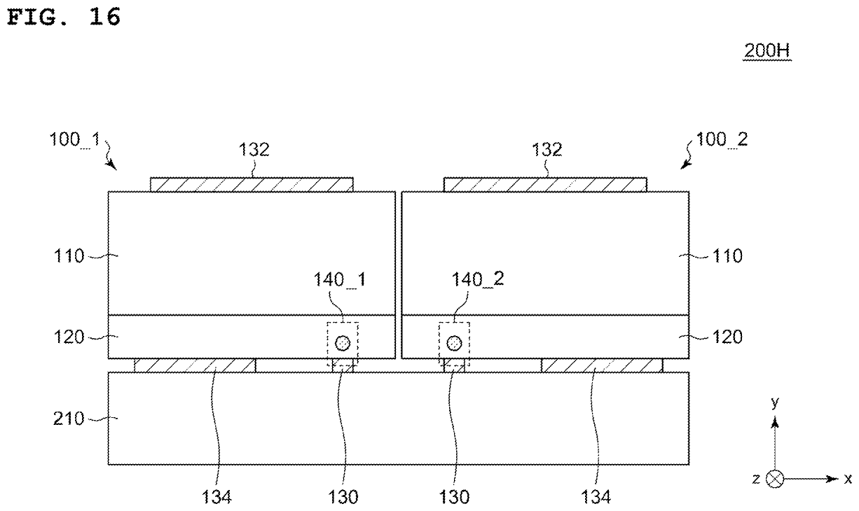

FIG. 16 is a cross-sectional view of a multi-beam semiconductor laser device 200H according to Example 8. In the multi-beam semiconductor laser device 200H, set m=1 and n=1, as is similar to Example 7. FIG. 16 differs from FIG. 13 in that the P-electrodes 130 are separated from the electrodes 134.

In Example 7 and Example 8, the semiconductor substrate 110 may be a tilted substrate, and these are also effective as an aspect of the present disclosure.

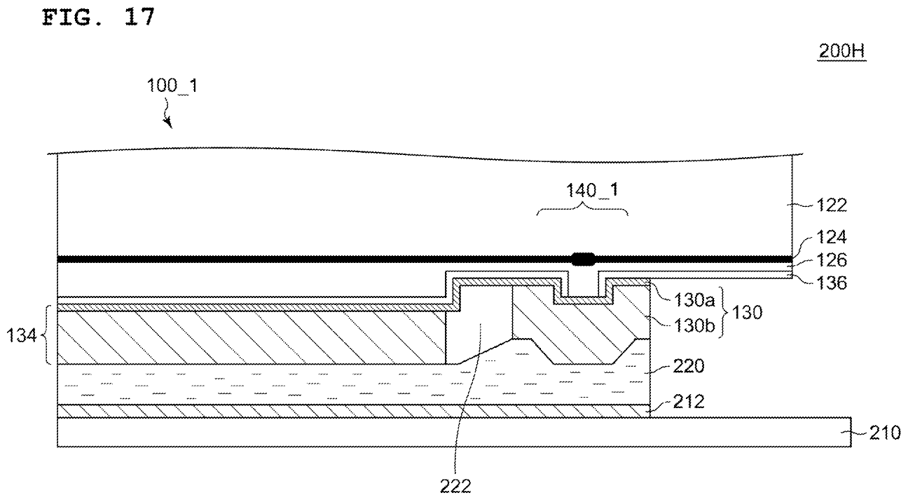

FIG. 17 is a diagram illustrating another bonding of the first semiconductor laser chip 100_1 with the submount 210 in a multi-beam semiconductor laser device 200H of FIG. 16. In this configuration, the P-electrode 130 and the electrode 134 are mounted to the land 212 that is common thereto.

### Example 9

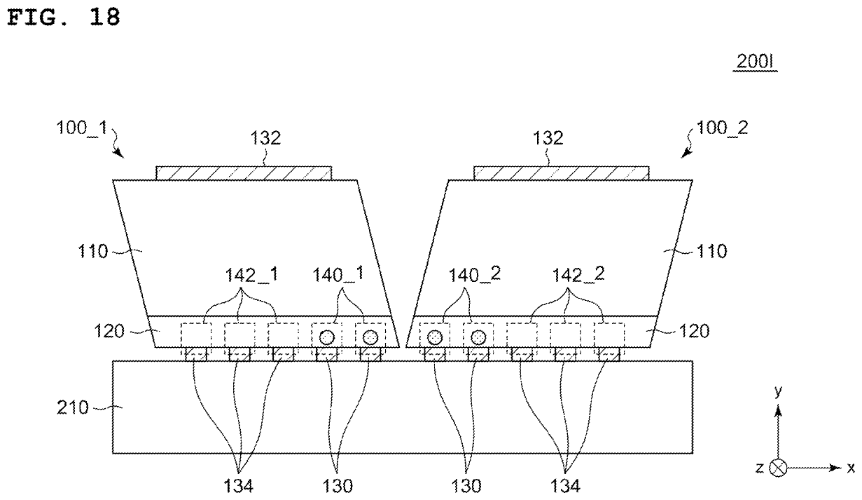

FIG. 18 is a cross-sectional view of a multi-beam semiconductor laser device 200I according to Example 9. The first semiconductor laser chip 100_1 has dummy resonators 142_1 in addition to the m laser resonators 140_1. The second semiconductor laser chip 100_2 has dummy resonators 142_2 in addition to the n laser resonators 140_2. In this example, set m−n=2. The dummy resonators 142 each have a waveguide structure (ridge structure) similar to that of each of the laser resonators 140, but it does not oscillate the laser and thus does not emit a beam. Hence, the multi-beam semiconductor laser device 200I in FIG. 13 is a multi-beam laser with m+n=4 channels.

### Variation Example

The embodiments describe the case of setting m=n; however, it is not limited to that case. The case of setting m≠n such as m=1 and n=2 may also be possible.

The embodiments describe the multi-beam semiconductor laser device 200 with the two semiconductor laser chips 100; however, the number of semiconductor laser chips 100 may be three or more.

The embodiments merely show the principle and application of the present disclosure or invention, and many variation examples and modifications in the arrangement are allowed for the embodiments to the extent that does not depart from the idea of the present disclosure or invention as stipulated in the scope of the claims.

What is claimed is:

1. A multi-beam semiconductor laser device comprising:
an edge-emitting first semiconductor laser chip; and
an edge-emitting second semiconductor laser chip,
wherein the first semiconductor laser chip and the second semiconductor laser chip are located adjacently to each other in a first direction,
the first semiconductor laser chip and the second semiconductor laser chip each include a semiconductor substrate and a stacked growth layer including a first conductive cladding layer, a light-emitting layer, and a second conductive cladding layer formed on the semiconductor substrate,
the first semiconductor laser chip includes m laser resonators (m≥1) extending in a second direction orthogonal to the first direction are formed,
the second semiconductor laser chip includes n laser resonators (n≥1) extending in the second direction, and
the m laser resonators of the first semiconductor laser chip are disposed at a position closer to a side where the second semiconductor laser chip is located adjacently than a side where the second semiconductor laser chip is not located adjacently.

2. The multi-beam semiconductor laser device according to claim 1, wherein the n laser resonators of the second semiconductor laser chip are disposed at a position closer to a side where the first semiconductor laser chip is located adjacently than a side where the first semiconductor laser chip is not located adjacently.

3. The multi-beam semiconductor laser device according to claim 1, wherein the first semiconductor laser chip and the second semiconductor laser chip are mounted to a submount with a junction-down method.

4. The multi-beam semiconductor laser device according to claim 1, wherein the m laser resonators (m≥2) are configured to be electrically and independently driven.

5. The multi-beam semiconductor laser device according to claim 1, wherein the semiconductor substrate of the first semiconductor laser chip is a tilted substrate having a tilted side face located on a side of the second semiconductor laser chip.

6. The multi-beam semiconductor laser device according to claim 1, further comprising a single submount that supports the first semiconductor laser chip and the second semiconductor laser chip.

7. The multi-beam semiconductor laser device according to claim 1, wherein when m+n≥3 is set, the (m+n) laser resonators formed in the first semiconductor laser chip and the second semiconductor laser chip are arranged with substantially equal intervals.

8. The multi-beam semiconductor laser device according to claim 1, wherein, of the (m+n) laser resonators formed in the first semiconductor laser chip and the second semiconductor laser chip, at least one laser resonator thereof has an oscillation wavelength different from that of at least another resonator thereof.

9. The multi-beam semiconductor laser device according to claim 1, wherein the first semiconductor laser chip and the second semiconductor laser chip are arranged with a gap that separates them.

10. The multi-beam semiconductor laser device according to claim 2, wherein the first semiconductor laser chip and the second semiconductor laser chip are mounted to a submount with a junction-down method.

11. The multi-beam semiconductor laser device according to claim 2, wherein the m laser resonators (m≥2) are configured to be electrically and independently driven.

12. The multi-beam semiconductor laser device according to claim 2, wherein the semiconductor substrate of the first semiconductor laser chip is a tilted substrate having a tilted side face located on a side of the second semiconductor laser chip.

13. The multi-beam semiconductor laser device according to claim 2, further comprising a single submount that supports the first semiconductor laser chip and the second semiconductor laser chip.

14. The multi-beam semiconductor laser device according to claim 2, wherein when m+n≥3 is set, the (m+n) laser resonators formed in the first semiconductor laser chip and the second semiconductor laser chip are arranged with substantially equal intervals.

15. The multi-beam semiconductor laser device according to claim 2, wherein, of the (m+n) laser resonators formed in the first semiconductor laser chip and the second semiconductor laser chip, at least one laser resonator thereof has an oscillation wavelength different from that of at least another resonator thereof.

16. The multi-beam semiconductor laser device according to claim 2, wherein the first semiconductor laser chip and the second semiconductor laser chip are arranged with a gap that separates them.
